(19) United States
(12) Patent Application Publication
(10) Pub. No.: US 2009/0253269 A1
(43) Pub. Date: Oct. 8, 2009

(54) SEMICONDUCTOR MANUFACTURING APPARATUS AND SEMICONDUCTOR DEVICE MANUFACTURING METHOD

(75) Inventor: Masayuki Tsuneda, Toyama-shi (JP)

Correspondence Address: BRUNDIDGE & STANGER, P.C., 1700 DIAGONAL ROAD, SUITE 330, ALEXANDRIA, VA, 22314, US

(73) Assignee: Hitachi-Kokusai Electric Inc.

(21) Appl. No.: 12/410,793

(22) Filed: Mar. 25, 2009

(30) Foreign Application Priority Data
Apr. 1, 2008 (JP) 2008-095365
Feb. 4, 2009 (JP) 2009-023716

(51) Int. Cl. H01L 21/465; C23C 16/46

(52) U.S. Cl. 438/758; 118/666; 257/E21.485

(57) ABSTRACT

A semiconductor manufacturing apparatus comprises: a substrate process chamber accommodating a substrate; a member heating the substrate, wherein the semiconductor manufacturing apparatus is a substrate processing apparatus for forming a film on the substrate by alternately supplying at least two process gases that react with each other to the substrate process chamber; gas supply units configured to supply the process gases independently; a cleaning gas supply source containing a cleaning gas for supplying the cleaning gas through the gas supply units; an exhaust control unit exhausting gas from the substrate process chamber through an exhaust pipe; an exhaust pipe heating unit heating the exhaust pipe; and a control unit controlling the exhaust pipe heating unit to keep the exhaust pipe higher than a predetermined temperature while a cleaning gas is exhausted from the substrate process chamber through the exhaust pipe by the exhaust control unit after the substrate is processed.

### CROSS-REFERENCE TO RELATED PATENT APPLICATION

This U.S. non-provisional patent application claims priority under 35 U.S.C. § 119 of Japanese Patent Application Nos. 2008-095365, filed on Apr. 1, 2008, and 2009-023716, filed on Feb. 4, 2009, in the Japanese Patent Office, the entire contents of which are hereby incorporated by reference.

### BACKGROUND OF THE INVENTION

1. Field of the Invention

The present invention relates to a semiconductor manufacturing apparatus.

For example, the present invention relates to a semiconductor manufacturing apparatus that can be used in a method of manufacturing a semiconductor integrated circuit device (hereinafter, referred to as an IC) to form a desired film on a semiconductor wafer (hereinafter, referred to as a wafer) for forming an IC on the wafer.

2. Description of the Prior Art

In an IC manufacturing method, a batch type vertical film forming apparatus is used for forming a film. An example of such an IC manufacturing method is disclosed in Patent Document 1.

Self cleaning (hereinafter, referred to as cleaning) is performed on such a conventional batch type vertical film forming apparatus by using gas containing fluorine (F) atoms such as nitrogen trifluoride (NF₃) so as to prevent deposition of contaminants on a reaction tube.

[Patent Document 1] Japanese Unexamined Patent Application Publication No. 2006-269532

In such a process apparatus, a material such as amine is selected as a substrate process raw material, and raw material process gas is supplied to a process vessel and is allowed to circulate in the process vessel, so as to perform a low temperature film forming process on a substrate accommodated in the process vessel. Amine such as tetrakis dimethylamino titanium (TDMAT) or tetrakis ethylmethylamino hafnium (TEMAH) may be used to form a nitride film such as a titanium nitride (TiN) film or an oxide film such as a hafnium dioxide (HfO₂) film.

Generally, although the process apparatus is a batch type vertical film forming apparatus configured to heat a substrate process chamber and an exhaust pipe during a substrate processing process, the temperature of the exhaust pipe is kept at a low temperature when the substrate process chamber and the exhaust pipe are cleaned. The reason for this is to prevent corrosion of the exhaust pipe caused by cleaning gas.

In the case where a TiN film is formed, cleaning can be performed using NF₃. In this case, at the same time with the cleaning, byproducts such as titan tetrafluoride (TiF₄) or fluorine (F₂) are produced.

TiF₄ sublimates at a high temperature of 284° C. at atmospheric pressure. Therefore, TiF₄ easily adheres to the exhaust pipe kept at a low temperature. Adhered TiF₄ reacts with moisture contained in the atmosphere and produces hydrofluoric (HF) acid. Thus, parts of the exhaust pipe where TiF₄ is adhered may corrode (rust).

### SUMMARY OF THE INVENTION

An object of the present invention is to provide a semiconductor manufacturing apparatus and a semiconductor device manufacturing method for preventing corrosion caused by cleaning.

According to an aspect of the present invention, there is provided a semiconductor manufacturing apparatus comprising: a substrate process chamber configured to accommodate a substrate; a member configured to heat the substrate, wherein the semiconductor manufacturing apparatus is a substrate processing apparatus configured to form a predetermined film on a surface of the substrate by alternately supplying at least two kinds of process gases that react with each other to the substrate process chamber; a plurality of gas supply units configured to supply the process gases independently; a cleaning gas supply source containing a cleaning gas for supplying the cleaning gas through the gas supply units; an exhaust control unit configured to exhaust a gas from an inside of the substrate process chamber through an exhaust pipe; an exhaust pipe heating unit configured to heat the exhaust pipe; and a control unit configured to control the exhaust pipe heating unit so as to keep the exhaust pipe at a temperature higher than a predetermined temperature while a cleaning gas supplied to the substrate process chamber is exhausted from the substrate process chamber through the exhaust pipe by the exhaust control unit after the substrate is processed.

According to another aspect of the present invention, there is provided a method of manufacturing a semiconductor device by using a substrate process apparatus comprising: a substrate process chamber configured to accommodate a substrate; a member configured to heat the substrate, wherein at least two kinds of process gases that react with each other are supplied to the substrate process chamber so as to form a predetermined film on a surface of the substrate; a plurality of gas supply pipes configured to supply the process gases independently; a cleaning gas supply source containing a cleaning gas for supplying the cleaning gas through the gas supply pipes; an exhaust control unit configured to exhaust a gas from an inside of the substrate process chamber through an exhaust pipe; an exhaust pipe heating unit configured to heat the exhaust pipe; and a control unit, the method comprising controlling the exhaust pipe heating unit to keep the exhaust pipe at a temperature higher than a predetermined temperature while the exhaust control unit supplies the cleaning gas to the substrate process chamber and exhausts the cleaning gas from the from the substrate process chamber through the exhaust pipe after the substrate is processed.

### BRIEF DESCRIPTION OF THE DRAWINGS

FIG. 1 is a longitudinal sectional view illustrating a process furnace of a batch type vertical film forming apparatus according to an embodiment of the present invention.

FIG. 2 is a schematic cross sectional view illustrating the process furnace of the batch type vertical film forming apparatus according to an embodiment of the present invention.

FIG. 3 is a perspective view illustrating a batch type vertical film forming apparatus according to an embodiment of the present invention.

FIG. 4 is a longitudinal sectional view illustrating a batch type vertical film forming apparatus according to an embodiment of the present invention.

### DETAILED DESCRIPTION OF THE PREFERRED EMBODIMENTS

Hereinafter, an embodiment of the present invention will be described with reference to the attached drawings.

In the current embodiment, a semiconductor manufacturing apparatus relevant to the present invention is configured as a vertical film forming apparatus in terms of structure and as an atomic layer deposition (ALD) apparatus in terms of function.

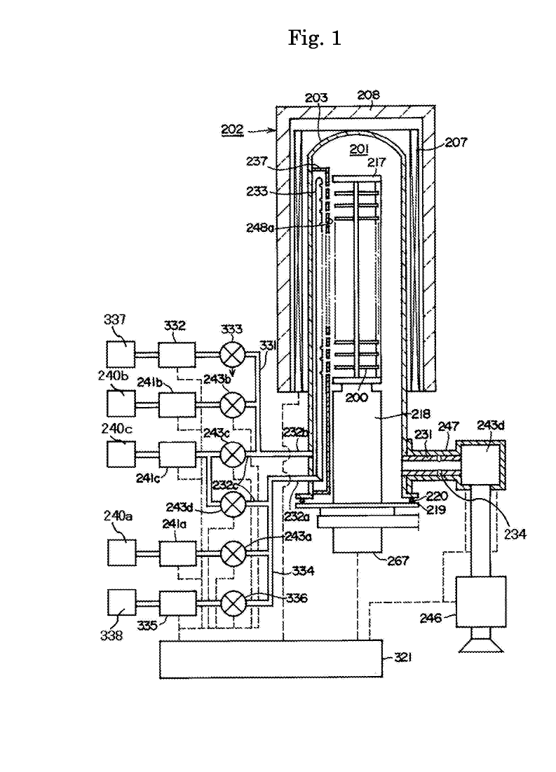

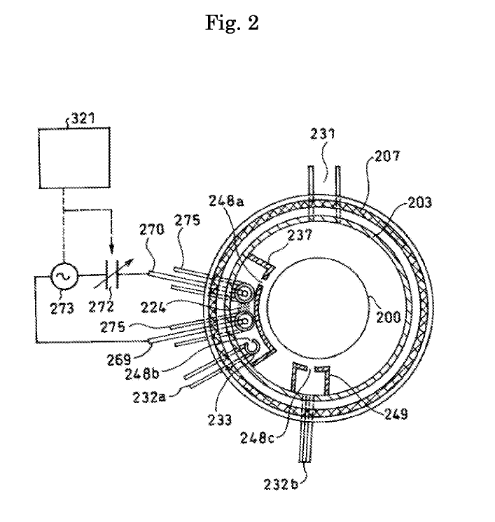

As shown in FIG. 1 and FIG. 2, the semiconductor manufacturing apparatus (hereinafter, referred to as an ALD apparatus) relevant to the current embodiment includes a process furnace 202, and the process furnace 202 includes a quartz reaction tube 203. The reaction tube 203 accommodates substrates such as wafers 200, and the reaction tube 203 constitutes a reaction vessel used as a process vessel. The reaction tube 203 is installed inside a heating unit such as a heater 207. An opened bottom side of the reaction tube 203 is air-tightly scaled by a cover such as a seal cap 219 with a seal member such as an O-ring 220 being disposed therebetween.

At the outside of the reaction tube 203 and the heater 207, an insulating member 208 is installed. The insulating member 208 is installed in a manner such that the insulating member 208 covers the upper end of the heater 207.

The process furnace 202 is constituted by the heater 207, the insulating member 208, the reaction tube 203, and the seal cap 219. In addition, a substrate process chamber 201 is constituted by the reaction tube 203, the seal cap 219, and a buffer chamber 237 formed in the reaction tube 203. A substrate holding unit such as a boat 217 is erected on the seal cap 219 with a quartz cap 218 being disposed therebetween. The quartz cap 218 constitutes a holder that holds the boat 217. The boat 217 is inserted in the process furnace 202. For batch processing, a plurality of wafers 200 are charged in the boat 217 in a manner such that the wafers 200 are horizontally oriented and vertically arranged in multiple stages in a tube axis direction. The heater 207 is configured to heat the wafers 200 placed in the process furnace 202 to a predetermined temperature.

At the process furnace 202, a plurality of (at least two) gas supply pipes 232a and 232b are installed. The two gas supply pipes 232a and 232b are used to supply at least two kinds of reaction gases that react with each other to the process furnace 202 in turns, and thus, the two gas supply pipes 232a and 232b are configured as supply pipes through which such process gases can be independently supplied.

The gas supply pipe 232a is configured to supply a first reaction gas from a first gas supply source 240a to the substrate process chamber 201 through a flow rate control unit such as a mass flow controller 241a, an on-off valve such as a valve 243a, and the buffer chamber 237 formed in the reaction tube 203.

The gas supply pipe 232b is configured to supply a second reaction gas from a second gas supply source 240b to the substrate process chamber 201 through a flow rate control unit such as a mass flow controller 241b, an on-off valve such as a valve 243b, and a gas supply unit 249.

A gas supply pipe 331 is connected to the upstream side of the gas supply pipe 232b. A first purge gas supply source 337, a flow rate control unit such as a mass flow controller 332, and an on-off valve such as a valve 333 are installed from the upstream side of the gas supply pipe 331.

A gas supply pipe 334 is connected to the upstream side of the gas supply pipe 232a. A second purge gas supply source 338, a flow rate control unit such as a mass flow controller 335, and an on-off valve such as a valve 336 are installed from the upstream of the gas supply pipe 334.

Cleaning gas supply pipes 232c are respectively connected to the gas supply pipes 232a and 232b from the downstream sides of valves 243c. A third gas (cleaning gas) supply source 240c, a flow rate control unit such as a mass flow controller 241c, and on-off valves such as the valves 243c are installed in this order from the upstream side of the cleaning gas supply pipes 232c.

The cleaning gas supply pipes 232c are used to supply cleaning gas to the substrate process chamber 201 through the mass flow controller 241c, the valves 243c, the buffer chamber 237, and the gas supply unit 249.

To prevent adhering of reaction byproducts, a pipe heater (not shown) is installed at the three gas supply pipes 232a, 232b, and 232c for heating the gas supply gas pipes 232a, 232b, and 232c to at least about 120° C.

An end of a gas exhaust pipe 231 is connected to the substrate process chamber 201 for exhaust gas from the substrate process chamber 201. The other end of the gas exhaust pipe 231 is connected to an exhaust unit such as a vacuum pump 246 (an exhaust control unit) through a valve 234. The gas exhaust pipe 231 is formed by connected a plurality of exhaust pipes, and an O-ring 234 is installed between the connected exhaust pipes. The inside of the substrate process chamber 201 is exhausted by the vacuum pump 246.

The valve 243d is an on-off valve that can be closed or opened for not exhausting or exhausting the substrate process chamber 201, and the opened area of the valve 243d can be adjusted for pressure adjustment. Herein, the vacuum pump 246 and the valve 243d will be also referred as an exhaust control unit.

To prevent adhering of byproducts, a heater 247 (an exhaust pipe heating unit) is installed at the gas exhaust pipe 231 for heating the gas exhaust pipe 231 to at least 150° C. The heater 247 is controlled by a controller 321.

At a circular arc shaped space between the inner wall of the reaction tube 203 and the wafers 200, the buffer chamber 237 is installed. The buffer chamber 237 is installed from the lower part to the upper part of the inner wall of the reaction tube 203 in the direction where the wafers 200 are arranged, so as to form a gas injection space.

Near an end part of an inner wall of the buffer chamber 237 adjacent to the wafers 200, gas supply holes 248a are formed to supply gas through the gas supply holes 248a. The gas supply holes 248a are formed in the direction toward the centerline of the reaction tube 203. Along a predetermined length from the lower side to the upper side in the direction where the wafers 200 are arranged, the gas supply holes 248a are arranged with the same pitch and have the same size.

Near the other end part of the inner wall of the buffer chamber 237 opposite to the gas supply holes 248a, a nozzle 233 is installed from the lower side to the upper side of the reaction tube 203 in the direction where the wafers 200 are arranged. A plurality of gas supply holes 248b are formed in the nozzle 233 for supply gas therethrough.

Like the gas supply holes 248a, the gas supply holes 248b are formed along a predetermined length in the direction where the wafers 200 are arranged. The gas supply holes 248b correspond to the gas supply holes 248a in a one-to-one manner.

If the pressure different between the buffer chamber 237 and the process furnace 202 is small, it is preferable that the gas supply holes 248b have the same size and pitch from the upstream side to the downstream side.

However, if the pressure different is large, it is preferable that the size of the gas supply holes 248b increase from the upstream side to the downstream side, or the pitch of the gas supply holes 248b decrease from the upstream side to the downstream side.

By adjusting the size and pitch of the gas supply holes 248b from the upstream side to the downstream side, gas can be injected with substantially the same flow rate at each gas supply holes 248b. Since gas injected through the gas supply holes 248b is first introduced into the buffer chamber 237, gas flow velocity can be uniformly maintained.

That is, in the buffer chamber 237, gas injected through the gas supply holes 248b decreases in particle velocity, and then, the gas is injected to the substrate process chamber 201 through the gas supply holes 248a. Owing to this period, when the gas injected through the gas supply holes 248b is re-injected through the gas supply holes 248a, the flow rate and velocity of the gas can be uniform.

Long and thin rod-shaped electrodes 269 and 270 are installed in the buffer chamber 237 in a state where electrode protecting tubes 275 protect the rod-shaped electrodes 269 and 270 from the upper sides to the lower sides of the rod-shaped electrodes 269 and 270. One of the rod-shaped electrodes 269 and 270 is connected to a high-frequency power source 273 through a matching device 272, and the other of the rod-shaped electrodes 269 and 270 is connected to a reference potential (earth potential). By turning on the high-frequency power source 273, gas supplied to a plasma generation region 224 between the rod-shaped electrodes 269 and 270 can be excited into a plasma state.

The electrode protecting tubes 275 can be inserted into the buffer chamber 237 in a state where the electrode protecting tubes 275 isolate the rod-shaped electrodes 269 and 270 from the inside atmosphere of the buffer chamber 237.

Here, if the insides of the electrode protecting tubes 275 are in the same state as the outside air (atmospheric state), the rod-shaped electrodes 269 and 270 inserted in the electrode protecting tubes 275 may be oxidized when heated by the heater 207.

Therefore, an inert gas purge mechanism is installed to fill or purge the insides of the electrode protecting tubes 275 with inert gas such as nitrogen gas so as to reduce oxygen concentration sufficiently for prevent oxidation of the rod-shaped electrodes 269 and 270.

The gas supply unit 249, which is independent of the nozzle 233 (gas supply unit), is installed on the inner wall of the reaction tube 203 at an angle of about 120 degrees from the gas supply holes 248a. When a plurality of gases are alternately supplied to the wafers 200 in a film forming process performed by an ALD method, the operation of supplying the plurality of gases are shared by the gas supply unit 249 and the buffer chamber 237.

The gas supply unit 249 includes a plurality of gas supply holes 248c. Like in the case of the buffer chamber 237, the gas supply holes 248c are formed in the vicinity of the wafers 200 with the same pitch for supply gas therethrough. The gas supply pipe 232b is connected to the lower side of the gas supply unit 249.

If the pressure different between the buffer chamber 237 and the substrate process chamber 201 is small, it is preferable that the gas supply holes 248c have the same size and pitch from the upstream side to the downstream side.

However, if the pressure different is large, it is preferable that the size of the gas supply holes 248c increase from the upstream side to the downstream side, or the pitch of the gas supply holes 248b decrease from the upstream side to the downstream side.

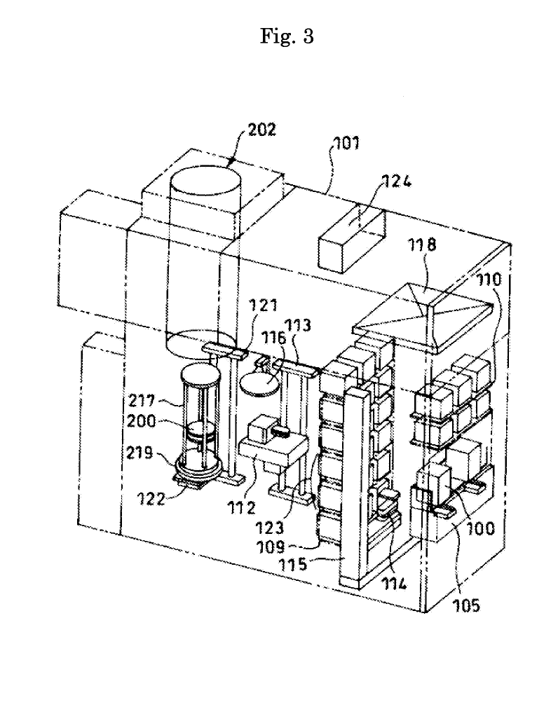

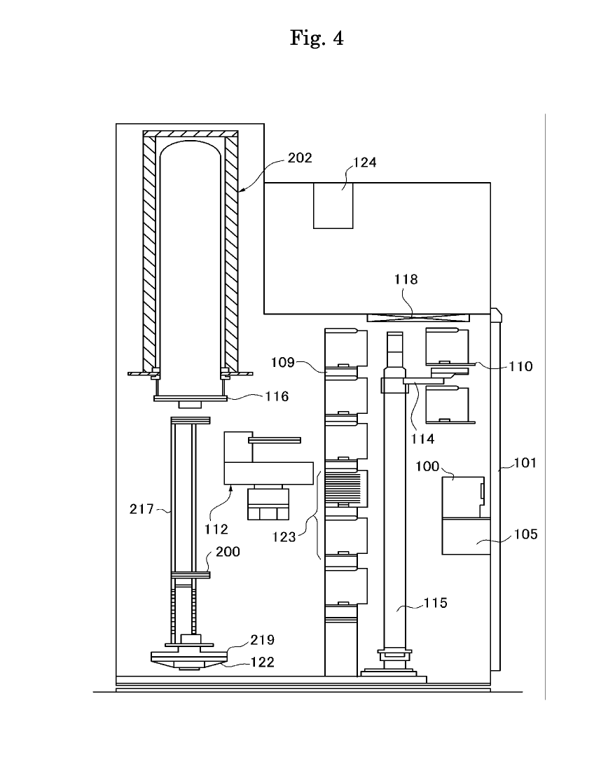

The boat 217 is installed at the center part of the reaction tube 203, and a plurality of wafers 200 can be vertically arranged in the boat 217 in multiple stages at the same intervals. The boat 217 is configured to be loaded into and unloaded from the reaction tube 203 by a boat elevator 121 illustrated in FIG. 3 and FIG. 4. FIG. 3 and FIG. 4 will be explained later.

A boat rotating mechanism 267 is installed as a rotary unit for improving process uniformity by rotating the boat 217, so that the boat 217 held by the quartz cap 218 can be rotated using the boat rotating mechanism 267.

The controller 321 (control unit) is connected to parts such as the mass flow controllers 241a, 241b, 241c, 332, and 335, the valves 243a, 243b, 243c, 243d, 333, and 336, the heater 207, the vacuum pump 246, the boat rotating mechanism 267, the boat elevator 121, the high-frequency power source 273, and the matching device 272.

The controller 321 controls various parts. For example, the controller 321 controls flow rate control operations of the mass flow controllers 241a, 241b, 332, and 335; opening/closing operations of the valves 243a, 243b, 333, and 336; opening/closing and pressure adjusting operations of the valve 243d; the temperature of the heater 207; turning-on and -off of the vacuum pump 246; the rotation speed of the boat rotating mechanism 267; lifting operations of the boat elevator 121; power supply of the high-frequency power source 273; and an impedance adjustment operation of the matching device 272.

Next, a method of forming a TiN film using tetrakis dimethylamino titanium (TDMAT) and NH₃ as process gases will be explained as an example of a film forming method using an ALD method. In the ALD method, at least two process gases that react with each other are alternately supplied to form a desired film on the surface of a substrate disposed in a process chamber.

First, wafers 200 on which films will be formed are charged into the boat 217, and the boat 217 is loaded into the process furnace 202 by the boat elevator 121. After the boat 217 is loaded, the following ALD steps 1 to 4 are sequentially performed.

[Step 1]

In step 1, the valve 243b installed at the gas supply pipe 232b, and the valve 243d installed at the gas exhaust pipe 231 are both opened 249, so that TDMAT of which the flow rate is controlled by the mass flow controller 241b can be supplied from the gas supply pipe 232b into the substrate process chamber 201 through the gas supply holes 248c of the gas supply unit 249, and at the same time, the TDMAT can be exhausted from the substrate process chamber 201 through the gas exhaust pipe 231.

When TDMAT is allowed to flow, the valve 243d is properly adjusted, and the inside pressure of the substrate process chamber 201 is kept at 20 Pa to 65 Pa. The mass flow controller 241b controls the flow rate of the TDMAT supply in the range from 0.2 g/min to 0.4 g/min. The wafers 200 are exposed to the TDMAT for 10 seconds to 60 seconds. At this time, the temperature of the heater 207 is set to a level suitable for keeping the temperature of the wafers 200 in the range from 150° C. to 200° C.

By allowing a flow of TDMAT, the TDMAT can be chemically adsorbed on the surfaces of the wafers 200.

In addition, while TDMAT flows, the heater 247 (exhaust unit heating unit) beats the gas exhaust pipe 231 and the O-ring 234. For example, the heater 247 is controlled to keep the gas exhaust pipe 231 at about 120° C.

At a low temperature, organic metal materials (in this step, TDMAT) easily adhere to the O-ring 234. If an organic metal material adheres to the O-ring 234, the organic metal material may enter the substrate process chamber 201 during the following steps 2 to 4, and thus, film quality may deteriorate or impurities may generated.

Therefore, while the wafers 200 are processed using an organic metal material, the heater 247 is operated to prevent adhering of the organic metal material to the O-ring 234. For example, since TDMAT easily adheres at a temperature lower than 120° C., the heater 247 is controlled to heat the gas exhaust pipe 231 to a temperature of 120° or higher.

Thereafter, the valve 243b is closed but the valve 243d is not closed, so as to evacuate the substrate process chamber 201 and exhaust remaining TDMAT.

[Step 2]

In step 2, after the substrate process chamber 201 is exhausted, the valve 333 is opened to supply hydrogen (H₂) gas to the substrate process chamber 201 through the gas supply pipe 331 for purging the substrate process chamber 201 with the H₂ gas while exhausting the substrate process chamber 201 using the vacuum pump 246 in a state where the valve 243d of the gas exhaust pipe 231 is opened. At this time, the mass flow rate controller 332 controls the flow rate of H₂ gas supply in the range from 500 sccm to 2000 sccm. In addition, the valve 243d is properly controlled to keep the inside pressure of the substrate process chamber 201 in the range from 20 Pa to 65 Pa. The hydrogen purge is performed for 10 seconds to 60 seconds.

By this hydrogen purge, the bond number of TDMAT coupled to a under layer film changes to produce reaction sites different from those existing before the hydrogen purge.

Thereafter, in a state where the valve 243d of the gas exhaust pipe 231 is opened, the valve 333 of the gas supply pipe 331 is closed, and the substrate process chamber 201 is exhausted to a pressure of 5 Pa to 10 Pa or lower by using the vacuum pump 246, in order to remove remaining hydrogen from the substrate process chamber 201.

[Step 3]

In step 3, after the substrate process chamber 201 is exhausted, in a state where the valve 243d of the gas exhaust pipe 231 is opened, the valve 243a of the gas supply pipe 232a is opened, so as to inject ammonia (NH₃) gas of which the flow rate is controlled by the mass flow controller 241a to the buffer chamber 237 from the gas supply pipe 232a through the gas supply holes 248b of the nozzle 233; and the high-frequency power source 273 applies high-frequency power across the rod-shaped electrodes 269 and 270 through the matching device 272 so as to excite the ammonia gas into plasma (an activated species); and the activated species is supplied to the substrate process chamber 201 while exhausting the supplied activated species through the gas exhaust pipe 231.

When ammonia gas is excited into plasma to flow the excited ammonia gas as an activated species, the valve 243d is properly adjusted to keep the inside pressure of the substrate process chamber 201 in the range from 20 Pa to 65 Pa. In addition, the mass flow controller 241a controls the flow rate of ammonia supply in the range from 3000 sccm to 5000 sccm. The wafers 200 are exposed to the activated species obtained by plasma-exciting ammonia for 10 seconds to 60 seconds. At this time, the temperature of the heater 207 is set to a level suitable for keeping the temperature of the wafers in the range from 150° C. to 200° C.

By supplying the activated species obtained by exciting ammonia into plasma, the activated species can be chemically adsorbed to the reaction sites formed by supplying TDMAT and performing a purge process using H₂ after the supply of TDMAT, so that Ti (titanium atom)-N (nitrogen atom) bonds can be formed.

Thereafter, the valve 243a of the gas supply pipe 232a is closed to stop supply of ammonia. In a state where the valve 243d of the gas exhaust pipe 231 is opened, the substrate process chamber 201 is exhausted to a pressure of 5 Pa to 10 Pa or lower by using the vacuum pump 246, so as to remove remaining ammonia from the substrate process chamber 201.

[Step 4]

In step 4, after the substrate process chamber 201 is exhausted, in a state where the valve 243d of the gas exhaust pipe 231 is opened, while exhausting the substrate process chamber 201 using the vacuum pump 246, the valve 336 is opened to supply hydrogen gas from the gas supply pipe 334 to the inside of the substrate process chamber 201 for purging the inside of the substrate process chamber 201. At this time, the mass flow controller 335 controls the flow rate of hydrogen gas in the range from 3000 sccm to 7000 sccm. In addition, the valve 243d is properly adjusted to keep the inside pressure of the substrate process chamber 201 in the range from 20 Pa to 65 Pa. This hydrogen purge is performed for 10 seconds to 60 seconds.

Thereafter, in a state where the valve 243d of the gas exhaust pipe 231 is opened, the valve 336 of the gas supply pipe 334 is closed to exhaust the substrate process chamber 201 to a pressure of 5 Pa to 10 Pa or lower by using the vacuum pump 246, so as to remove remaining hydrogen gas from the substrate process chamber 201.

One cycle including the above-described steps 1 to 4 is repeated a plurality of times, in order to form titanium nitride films on the wafers to a predetermined thickness.

In the ALD steps (that is, steps 1 to 4), it is preferable that the heater 247 (exhaust pipe heating unit) continuously heat the gas exhaust pipe 231 to keep the gas exhaust pipe 231 at a temperature equal to or higher than a predetermined valve.

In steps 2 and 3, if heating is suspended by stopping the operation of the heater 247, a predetermined time is necessary for re-heating to a predetermined temperature, and thus the throughput may decrease.

Therefore, in steps 1 to 4, the heater 247 is controlled to continuously heat the gas exhaust pipe 231.

However, when the above-described film forming steps are performed, a titanium nitride film is also deposited on a surface of the process furnace 202 exposed to process gas.

If the titanium nitride film is deposited to a thickness equal to or greater than a predetermined value (for example, 3000 Å), film separation occurs, and thus contaminants are generated on the wafers 200.

Therefore, in the current embodiment, before the thickness of a deposition film increases to a level where film separation occurs or after a predetermined number of cycles (that is, after steps 1 to 4 are repeated predetermined times), a cleaning step is performed.

Hereinafter, an explanation will be given on a cleaning step where nitride trifluoride (NF₃) gas is supplied to the process furnace 202 for removing a film deposited on the process furnace 202.

The inside temperature of the substrate process chamber 201 is increased to a predetermined temperature (an etching temperature by nitrogen trifluoride) by using the heater 207.

Thereafter, after opening the valves 243c and 243d, NF₃ is supplied as cleaning gas to the inside of the substrate process chamber 201 from the cleaning gas supply pipes 232c through buffer chamber 237 and the gas supply unit 249.

The supplied NF₃ removes a deposited film by etching reaction.

At this time, the controller 321 controls the heater 247 to maintain the gas exhaust pipe 231 at a temperature equal to or higher than 120° C., and the controller 321 controls the vacuum pump 246 to maintain the inside of the substrate process chamber 201 at a pressure equal to or lower than 2000 Pa.

When cleaning is performed using NF₃ in a TiN film forming process, byproducts such as TiF₄ or F₂ are generated. Since the sublimation temperature of TiF₄ is high at 284° C. under atmospheric pressure (1013 hPa), the byproduct easily accumulates at the gas exhaust pipe 231. The TiF₄ remaining at the gas exhaust pipe 231 reacts with moisture contained in the atmosphere to produce hydrogen fluoride (HF) that corrodes (rusts) the gas exhaust pipe 231.

However, according to the investigation by the inventor, when cleaning is performed, adhesion of TiF₄ can be prevented by keeping the pressure of the substrate process chamber 201 equal to or lower than 2000 Pa and the heating temperature of the heater 247 equal to or higher than 120° C.

Therefore, in the current embodiment, the temperature of the gas exhaust pipe 231 is kept equal to or higher than 120° C. by using the heater 247 to prevent accumulation of TiF₄ at the gas exhaust pipe 231.

As a result, hydrofluoric (HF) acid is not produced by a reaction between TiF₄ remaining at the gas exhaust pipe 231 and moisture contained in the atmosphere, and thus the gas exhaust pipe 231 can be protected from corrosion (rust) caused by hydrofluoric (HF) acid.

After a predetermined time for the cleaning step is passed, supply of cleaning gas is stopped, and a seasoning process is performed on the inside of the process furnace 202 to return to the state where ALD steps (film forming steps) can be performed.

In the cleaning step, it is preferable that the operation of the heater 247 be continued from the above-described ALD steps.

If heating is suspended after the ALD steps by stopping the operation of the heater 247, a predetermined time is necessary for re-heating to a predetermined temperature, and thus the throughput may decrease.

Therefore, during the period from the ALD steps to the cleaning step, the heater 247 is controlled to heat the gas exhaust pipe 231.

In addition, although a method of using TDMAT and NH₃ is explained as an example of an ALD method, the present invention is not limited thereto. For example, TiCl₄ and NH₄ can be used. In this case, in the ALD steps and the cleaning step where NF₃ is supplied to the substrate process chamber 201, temperature is kept equal to or higher than 150° C.

In addition, although NH₃ is activated by exciting the NH₃ into plasma, the present invention is not limited thereto. For example, NH₃ can be activated by heating the NH₃ using the heater 207.

Next, with reference to FIG. 3 and FIG. 4, a substrate processing apparatus will be explained as an ALD apparatus relevant to an embodiment of the present invention.

At the front side of the inside of a housing 101, a cassette stage 105 is installed. The cassette stage 105 is configured as a holder receiving member so that cassettes 100 used as substrate holders can be transferred between the cassette stage 105 and an outer carrying device (not shown).

At the rear side of the cassette stage 105, a cassette elevator 115 is installed as a lift unit, and at the cassette elevator 115, a cassette transfer device 114 is installed as a carrying unit.

At the rear side of the cassette elevator 115, a cassette self 109 is installed for placing cassettes 100 thereon, and at the upside of the cassette stage 105, an auxiliary cassette self 110 is installed. At the upside of the auxiliary cassette self 110, a cleaning unit 118 is installed. The cleaning unit 118 is used to circuit clean air in the housing 101.

At the rear upper side of the housing 101, a process furnace 202 is installed, and at the lower side of the process furnace 202, a boat elevator 121 is installed. A boat 217 is used as a substrate holding unit to hold wafers 200 horizontally in multiple stages, and the boat elevator 121 is used to raise/lower the boat 217 to/from the process furnace 202.

At the boat elevator 121, a lift member 122 is installed, and at a leading end of the lift member 122, a seal cap 219 is installed as a cover. The seal cap 219 supports the boat 217 vertically.

Between the boat elevator 121 and the cassette self 109, a transfer elevator 113 is installed as a lift unit, and at the transfer elevator 113, a wafer transfer device 112 is installed as a carrying unit. Beside the boat elevator 121, a furnace port shutter 116 having an opening/closing mechanism is installed as a closing unit for air-tightly closing the bottom side of the process furnace 202.

A cassette 100 charged with wafers 200 is carried onto the cassette stage 105 from the enter carrying device (not shown) in a manner such that the wafers 100 face upward, and then the cassette 100 is rotated on the cassette stage 105 by 90 degrees to orient the wafers 200 horizontally.

Next, the cassette 100 is carried from the cassette stage 105 to the cassette self 109 or the auxiliary cassette self 110 by a combination of vertical and transversal operations of the cassette elevator 115 and forward/backward and rotational operations of the cassette transfer device 114.

The cassette self 109 includes a transfer self 123, and the wafer transfer device 112 carries wafers 200 from a cassette 100 accommodated on the transfer self 123. For this, a cassette 100 is transferred to the transfer self 123 by the cassette elevator 115 and the cassette transfer device 114.

After a cassette 100 is transferred onto the transfer self 123, forward/backward and rotational operations of the wafer transfer device 112, and vertical operations of the transfer elevator 113 are performed in combination, so as to transfer wafers 200 from the cassette 100 placed on the transfer self 123 to the boat 217 placed at a lower position.

After a predetermined number of wafers 200 are transferred, the boat 217 is loaded into the process furnace 202 by the boat elevator 121, and the process furnace 202 is air-tightly closed by the seal cap 219. In the air-tightly closed process furnace 202, the wafers 200 are heated and processed by process gas supplied to the inside of the process furnace 202.

After the wafers 200 are processed, in the reverse order, the wafers 200 are transferred from the boat 217 to the cassette 100 of the transfer self 123, and then the cassette 100 is transferred by the cassette transfer device 114 from the transfer self 123 to the cassette stage 105 where the cassette 100 is carried to the outside of the housing 101 by the outer carrying device (not shown).

When the boat 217 is placed at a lower position, the bottom side of the process furnace 202 is air-tightly closed by the furnace port shutter 116 to prevent inflow of outside air into the process furnace 202.

In addition, carrying operations, for example, the carrying operation of the cassette transfer device 114, axe controlled by a carrying operation control unit 124.

According to the present invention, adhering of TiF₄ generated by a cleaning process can be controlled to prevent corrosion of the exhaust pipe caused by the adhering of TiF₄.

The present invention also includes the following embodiments.

(Supplementary Note 1)

According to a preferred embodiment of the present invention, there is provided a semiconductor manufacturing apparatus comprising: a substrate process chamber configured to accommodate a substrate; a member configured to heat the substrate, wherein the semiconductor manufacturing apparatus is a substrate processing apparatus configured to form a predetermined film on a surface of the substrate by alternately supplying at least two kinds of process gases that react with each other to the substrate process chamber; a plurality of gas supply units configured to supply the process gases independently; a cleaning gas supply source containing a cleaning gas for supplying the cleaning gas through the gas supply units; an exhaust control unit configured to exhaust a gas from an inside of the substrate process chamber through an exhaust pipe; an exhaust pipe heating unit configured to heat the exhaust pipe; and a control unit configured to control the exhaust pipe heating unit so as to keep the exhaust pipe at a temperature higher than a predetermined temperature while a cleaning gas supplied to the substrate process chamber is exhausted from the substrate process chamber through the exhaust pipe by the exhaust control unit after the substrate is processed.

(Supplementary Note 2)

In the semiconductor manufacturing apparatus of Supplementary Note 1, the exhaust pipe may comprise an V-ring.

(Supplementary Note 3)

In the semiconductor manufacturing apparatus of Supplementary Note 2, the control unit may control the exhaust pipe heating unit to heat the exhaust pipe while a process gas is supplied to the substrate process chamber or while a cleaning gas is supplied to the substrate process chamber.

(Supplementary Note 4)

In the semiconductor manufacturing apparatus of Supplementary Note 2, the control unit may control the exhaust pipe heating unit, so that the exhaust pipe heating unit operates at a temperature equal to or higher than a predetermined temperature while a process gas is supplied to the substrate process chamber.

(Supplementary Note 5)

In the semiconductor manufacturing apparatus of Supplementary Note 1, wherein the control unit may control the exhaust pipe heating unit to heat the exhaust pipe while a process gas is supplied to the substrate process chamber or while a cleaning gas is supplied to the substrate process chamber.

(Supplementary Note 6)

In the semiconductor manufacturing apparatus of Supplementary Note 1, the control unit may control the exhaust pipe heating unit, so that the exhaust pipe heating unit operates at a temperature equal to or higher than a predetermined temperature while a process gas is supplied to the substrate process chamber.

(Supplementary Note 7)

In the semiconductor manufacturing apparatus of Supplementary Note 1, wherein the at least two kinds of process gases may comprise tetrakis dimethylamino titanium (TDMAT) and ammonia (NH₃), and the predetermined temperature may be about 120° C.

(Supplementary Note 8)

In the semiconductor manufacturing apparatus of Supplementary Note 1, the at least two kinds of process gases may comprise titanium tetrachloride (TiCl₄) and ammonia (NH₃), and the predetermined temperature may be about 150° C.

(Supplementary Note 9)

According to another preferred embodiment of the present invention, there is provided a method of manufacturing a semiconductor device by using a substrate process apparatus comprising: a substrate process chamber configured to accommodate a substrate; a member configured to heat the substrate, wherein at least two kinds of process gases that react with each other are supplied to the substrate process chamber so as to form a predetermined film on a surface of the substrate; a plurality of gas supply pipes configured to supply the process gases independently; a cleaning gas supply source containing a cleaning gas for supplying the cleaning gas through the gas supply pipes; an exhaust control unit configured to exhaust a gas from an inside of the substrate process chamber through an exhaust pipe; an exhaust pipe heating unit configured to heat the exhaust pipe; and a control unit, the method comprising controlling the exhaust pipe heating unit to keep the exhaust pipe at a temperature higher than a predetermined temperature while the exhaust control unit supplies the cleaning gas to the substrate process chamber and exhausts the cleaning gas from the from the substrate process chamber through the exhaust pipe after the substrate is processed.

According to the above-described embodiments, the following effects can be attained.

1) When cleaning is performed using a cleaning gas, the gas exhaust pipe is kept at a high temperature (120° C. or higher) to prevent accumulation of byproducts at the gas exhaust pipe, so that the gas exhaust pipe can be prevented from being corroded (rusted) by reaction between byproducts remaining on the gas exhaust pipe and moisture contained in the atmosphere.

2) Since corrosion (rusting) of the gas exhaust pipe can be prevented, members of the process furnace such as the gas exhaust pipe can be less frequently replaced with new members, and thus maintenance efficiency can be improved.

3) Since the cleaning gas supply pipe (line) is connected using a plurality of valves to the plurality of gas supply pipes configured to supply a plurality of kinds of process gases to the process furnace, the gas supply pipes can be also used to supply cleaning gas, and thus deposition of byproducts, for example, on a plurality of gas exhaust pipes can be prevented. Therefore, the lifetime of the gas supply pipes can be increased, and the gas supply pipes can be less frequently replaced with new ones, thereby improving the rate of operation of the ALD apparatus.

In addition, the present invention is not limited to the above-described embodiments. That is, many different embodiments are possible within the scope and spirit of the present invention.

For example, instead of using nitrogen trifluoride (NF₃) as cleaning gas, other gas such as C₂F₆, C₃F₃, and COF₂ can be used as cleaning gas.

The exhaust pipe is heated to 120° C. or higher.

The film forming process is not limited to forming of a titanium nitride film. That is, other thin films such as a silicon nitride film, a silicon oxide film, an oxide film, a nitride film, a metal film, and a semiconductor film (for example, a polysilicon film) can be formed.

In the above-described embodiments, a bath type vertical film forming apparatus operating according to an ALD method is described; however, the present invention can be applied to other semiconductor manufacturing apparatuses such as an oxide film forming apparatus, a diffusion apparatus, and an annealing apparatus.

In the above-described embodiments, processing of a wafer is explained; however, other objects such as a photomask, a printed circuit board, a liquid crystal panel, a compact disk, and a magnetic disk can be processed.

What is claimed is:

1. A semiconductor manufacturing apparatus comprising:
a substrate process chamber configured to accommodate a substrate;
a member configured to heat the substrate, wherein the semiconductor manufacturing apparatus is a substrate processing apparatus configured to form a predetermined film on a surface of the substrate by alternately supplying at least two kinds of process gases that react with each other to the substrate process chamber;
a plurality of gas supply units configured to supply the process gases independently;
a cleaning gas supply source containing a cleaning gas for supplying the cleaning gas through the gas supply units;
an exhaust control unit configured to exhaust a gas from an inside of the substrate process chamber through an exhaust pipe;
an exhaust pipe heating unit configured to heat the exhaust pipe; and
a control unit configured to control the exhaust pipe heating unit so as to keep the exhaust pipe at a temperature higher than a predetermined temperature while a cleaning gas supplied to the substrate process chamber is exhausted from the substrate process chamber through the exhaust pipe by the exhaust control unit after the substrate is processed.

2. The semiconductor manufacturing apparatus of claim 1, wherein the exhaust pipe comprises an O-ring.

3. The semiconductor manufacturing apparatus of claim 2, wherein the control unit controls the exhaust pipe heating unit to heat the exhaust pipe while a process gas is supplied to the substrate process chamber or while a cleaning gas is supplied to the substrate process chamber.

4. The semiconductor manufacturing apparatus of claim 2, wherein the control unit controls the exhaust pipe heating unit, so that the exhaust pipe heating unit operates at a temperature equal to or higher than a predetermined temperature while a process gas is supplied to the substrate process chamber.

5. The semiconductor manufacturing apparatus of claim 1, wherein the control unit controls the exhaust pipe heating unit to heat the exhaust pipe while a process gas is supplied to the substrate process chamber or while a cleaning gas is supplied to the substrate process chamber.

6. The semiconductor manufacturing apparatus of claim 1, wherein the control unit controls the exhaust pipe heating unit, so that the exhaust pipe heating unit operates at a temperature equal to or higher than a predetermined temperature while a process gas is supplied to the substrate process chamber.

7. The semiconductor manufacturing apparatus of claim 1, wherein the at least two kinds of process gases comprise tetrakis dimethylamino titanium (TDMAT) and ammonia (NH₃), and the predetermined temperature is about 120° C.

8. The semiconductor manufacturing apparatus of claim 1, wherein the at least two kinds of process gases comprise titanium tetrachloride (TiCl₄) and ammonia (NH₃), and the predetermined temperature is about 150° C.

9. A method of manufacturing a semiconductor device by using a substrate process apparatus comprising: a substrate process chamber configured to accommodate a substrate; a member configured to heat the substrate, wherein at least two kinds of process gases that react with each other are supplied to the substrate process chamber so as to form a predetermined film on a surface of the substrate; a plurality of gas supply pipes configured to supply the process gases independently; a cleaning gas supply source containing a cleaning gas for supplying the cleaning gas through the gas supply pipes; an exhaust control unit configured to exhaust a gas from an inside of the substrate process chamber through an exhaust pipe; an exhaust pipe heating unit configured to heat the exhaust pipe; and a control unit,
the method comprising controlling the exhaust pipe heating unit to keep the exhaust pipe at a temperature higher than a predetermined temperature while the exhaust control unit supplies the cleaning gas to the substrate process chamber and exhausts the cleaning gas from the from the substrate process chamber through the exhaust pipe after the substrate is processed.
